(19) United States
(12) Patent Application Publication
(10) Pub. No.: US 2025/0315936 A1
(43) Pub. Date: Oct. 9, 2025

(54) DEVICE AND METHOD FOR INSPECTING DISPLAY APPARATUS

(71) Applicant: Samsung Display Co., Ltd., Yongin-Si (KR)

(72) Inventors: Kiwook Lee, Yongin-si (KR); Iljae Lee, Yongin-si (KR); Jinho Choi, Yongin-si (KR)

(21) Appl. No.: 19/078,661

(22) Filed: Mar. 13, 2025

(30) Foreign Application Priority Data
Apr. 8, 2024 (KR) 10-2024-0047462

(51) Int. Cl. G06T 7/00; B65G 54/02

(52) U.S. Cl. CPC G06T 7/0004; B65G 54/02; G06T 2207/30148

(57) ABSTRACT

Provided are a device and method for inspecting a display apparatus. The device includes an electromagnetic transfer unit including a first electromagnetic transfer unit extending in a first direction and a second electromagnetic transfer unit spaced apart from and extending parallel to the first electromagnetic transfer unit, a stage that is arranged on the electromagnetic transfer unit to support a display substrate, and a robotic transfer unit arranged between the first electromagnetic transfer unit and the second electromagnetic transfer unit and extending in the first direction.

### CROSS-REFERENCE TO RELATED APPLICATION

This application is based on and claims priority, under 35 U.S.C. § 119, to Korean Patent Application No. 10-2024-0047462 filed on Apr. 8, 2024 in the Korean Intellectual Property Office, the disclosure of which is incorporated by reference herein in its entirety.

### BACKGROUND

### 1. Field

One or more embodiments relate to a device and method for inspecting a display apparatus, and more particularly, to a device and method for inspecting a display apparatus which enable easier detection of defects.

### 2. Description of the Related Art

Portable electronic devices are widely used. In addition to compact mobile devices such as mobile phones, tablet personal computers (PCs) have recently been in wide use.

Such portable electronic devices include display apparatuses that support various functions and provide users with visual information such as images or moving images. Recently, as the sizes of components for driving a display apparatus are reduced, a higher proportion of space is taken up by the display apparatus in an electronic device, and a display apparatus with a structure that is foldable to a certain angle from a flat state has been developed.

During the processes of manufacturing a display apparatus or after the completion of manufacturing, images may be captured to inspect the curvature, etc. of the display apparatus.

The background technology stated herein is technical information that the inventor either possessed to develop the disclosure or acquired in the course of deriving the disclosure and is not necessarily known to the general public before the filing of the disclosure.

### SUMMARY

When images are captured to inspect a display apparatus, the display apparatus is being transferred, and thus, there is difficulty in obtaining images matching with the actual object.

To solve the aforementioned problems, one or more embodiments include a device and method for inspecting a display apparatus capable of obtaining images matching the actual object in an inspection area.

The embodiments provided in this disclosure are examples, and are not intended to be exhaustive or limiting. Additional aspects will be set forth in part in the description which follows and, in part, will be apparent from the description, or may be learned by practice of the presented embodiments of the disclosure.

According to one or more embodiments, a device for inspecting a display apparatus includes an electromagnetic transfer unit including a first electromagnetic transfer unit extending in a first direction and a second electromagnetic transfer unit spaced apart from and extending parallel to the first electromagnetic transfer unit, a stage that is arranged on the electromagnetic transfer unit to support a display substrate, and a robotic transfer unit arranged between the first electromagnetic transfer unit and the second electromagnetic transfer unit and extending in the first direction.

The device may further include a vision unit arranged in an inspection area that includes a segment of the electromagnetic transfer unit for inspection of the display substrate.

The robotic transfer unit may be located in the inspection area on an opposite side of the stage from the vision unit.

The robotic transfer unit may be configured to transfer the stage at uniform velocity.

A length of the robotic transfer unit may be less than a length of the electromagnetic transfer unit.

A path of the robotic transfer unit may overlap a portion of the path of the electromagnetic transfer unit.

The robotic transfer unit may further include a guide portion extending in a first direction, a moving unit positioned adjacent to the guide portion and moving along the guide portion, and a clamping unit arranged on the moving unit and shaped to couple to the stage.

The robotic transfer unit may further include a ball screw arranged under the guide portion, extending in the first direction, and including a male thread.

The moving unit may include a through-hole with a female thread, the ball screw extending through the through-hole and moving the moving unit according to a rotation of the ball screw.

The clamping unit has a U shape.

The stage may include a receiving hole through which at least one end of the U-shaped clamping unit extends.

The electromagnetic transfer unit may include a rail including a plurality of electromagnets arranged apart from each other in the first direction, and a sliding unit including a permanent magnet and configured to slidably move on the rail.

A plurality of robotic transfer units may be provided, and the plurality of robotic transfer units may be spaced apart to be parallel with each other and extend in the first direction.

According to one or more embodiments, a method of inspecting a display apparatus includes mounting a display substrate on a stage, transferring the stage on an electromagnetic transfer unit, transferring the stage by a robotic transfer unit in an inspection area for inspection of the display substrate, and inspecting the display substrate by using a vision unit arranged in the inspection area.

The method may further include transferring the stage along the robotic transfer unit at uniform velocity.

The transferring of the stage may include rotating a ball screw that is positioned under a guide portion of the robotic transfer unit and extending in a first direction, inserting the ball screw through a threaded hole in a moving unit, and engaging a clamping unit arranged on the moving unit to clamp the stage.

The transferring of the stage may further include rotating the ball screw at a constant speed to move the moving unit at uniform velocity in the first direction.

The method may further include transferring the stage in an accelerated motion along the electromagnetic transfer unit in a non-inspection area.

The electromagnetic transfer unit may include a first electromagnetic transfer unit extending in the first direction and a second electromagnetic transfer unit spaced apart from and parallel to the first electromagnetic transfer unit, and the robotic transfer unit may be arranged between the first electromagnetic transfer unit and the second electromagnetic transfer unit and extend in the first direction.

The robotic transfer unit may be shorter than the electromagnetic transfer unit.

Other aspects, features, and advantages other than those described above will become apparent from the following detailed description, claims and drawings for carrying out the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 is a schematic cross-sectional view of a display apparatus according to an embodiment, taken along a line II-II′ of FIG. 1;

FIG. 3 is a schematic perspective view of a device for inspecting a display apparatus, according to an embodiment;

FIG. 4 is a schematic perspective view of an electromagnetic transfer unit according to an embodiment;

FIG. 5 is an enlarged perspective view schematically showing a robotic transfer unit according to an embodiment; and

FIG. 6A schematically shows an image captured using a device for inspecting a display apparatus according to an embodiment.

FIG. 6B and FIG. 6C schematically show images captured using a device for inspecting a display apparatus according to one or more Comparative Examples.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, particular embodiments will be shown in the drawings and described in detail in the written description. The attached drawings for illustrating embodiments of the disclosure are referred to in order to gain a sufficient understanding of the present disclosure, the merits thereof, and the objectives accomplished by the implementation of the disclosure. The disclosure may, however, be embodied in many different forms and should not be construed as being limited to the embodiments set forth herein.

Hereinafter, one or more embodiments of the disclosure will be described in detail with reference to the accompanying drawings. Like reference numerals in the drawings denote like elements, and repeated descriptions thereof are omitted.

It will be understood that although ordinal terms “first,” “second,” etc. may be used herein to describe various elements, these elements should not be limited to any order or priority by these terms, and these terms are only used to distinguish one element from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or elements, but do not preclude the presence or addition of one or more other features or elements.

It will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated for convenience of explanation. In other words, since sizes and thicknesses of elements in the drawings are arbitrarily illustrated for convenience of explanation, the following embodiments are not limited thereto.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

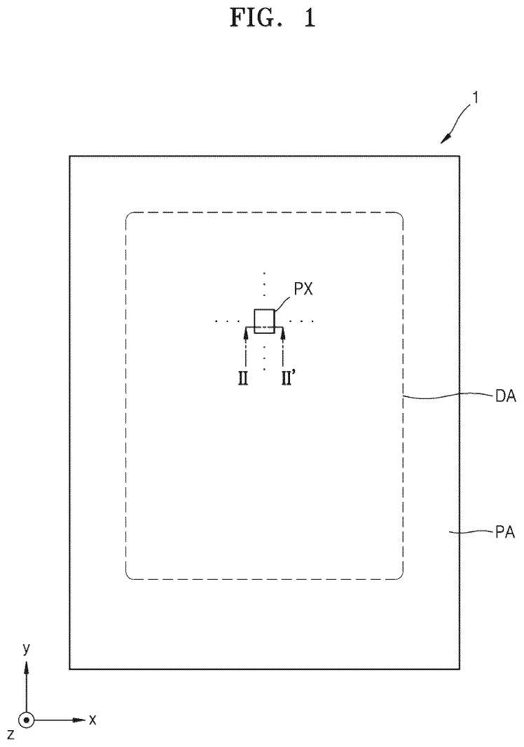

FIG. 1 is a schematic plan view of a display apparatus according to an embodiment.

Referring to FIG. 1, a display apparatus 1 according to an embodiment may include a display area DA and a peripheral area PA outside the display area DA. The display apparatus 1 may provide an image through an array of pixels PX that are two-dimensionally arranged in the display area DA.

The peripheral area PA may be an area where no images are displayed and may entirely or partially surround the display area DA. In the peripheral area PA, drivers or the like configured to provide electrical signals or power to pixel circuits respectively corresponding to the pixels PX may be arranged. In the peripheral area PA, a pad that may be electrically connected to an electronic component or a printed circuit board may be arranged.

Hereinafter, it is described that the display apparatus 1 includes organic light-emitting diodes (OLEDs) as light-emitting elements, but the display apparatus 1 is not limited thereto. In another embodiment, the display apparatus 1 may be a light-emitting display apparatus including inorganic light-emitting diodes, that is, an inorganic light-emitting display apparatus. The inorganic light-emitting diode may include a PN diode including materials based on an inorganic semiconductor. When a voltage is applied to the PN junction diode in a forward direction, electrons and holes may be injected, and energy generated from the recombination of the electrons and holes may be converted into light energy so that certain colors of light may be emitted. The inorganic light-emitting diode may have a width of several to several hundred micrometers, and in some embodiments, the inorganic light-emitting diode may be referred to as a micro LED. In another embodiment, the display apparatus 1 may be a quantum dot light-emitting display apparatus.

The display apparatus 1 may be incorporated into various products, for example, a portable electronic apparatus such as a mobile phone, a smartphone, a tablet personal computer (PC), a mobile communication terminal, a personal digital assistant, an e-book terminal, a portable multimedia player (PMP), a navigation device, or an ultra-mobile PC (UMPC), a television (TV), a laptop, a monitor, a billboard, an Internet of Things (IoT) device, and the like. Also, in an embodiment, the display apparatus 1 may be used in a wearable device, such as a smartwatch, a watch phone, an eyewear display, or a head-mounted display (HMD). Also, in an embodiment, the display apparatus 1 may be used as a display screen in an instrument cluster of a vehicle, a center information display (CID) mounted on a center fascia or a dashboard of a vehicle, a room mirror display replacing a side-view mirror of a vehicle, or a car headrest monitor provided for rear-seat entertainment.

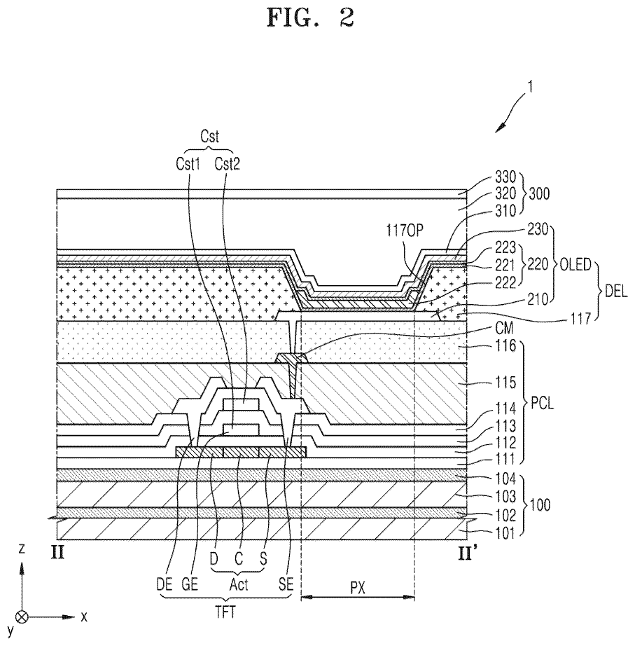

FIG. 2 is a schematic cross-sectional view of a display apparatus according to an embodiment, taken along a line II-II′ of FIG. 1.

Referring to FIG. 2, the display apparatus 1 may have a stack structure including a substrate 100, a pixel circuit layer PCL, a display element layer DEL, and an encapsulation layer 300.

The substrate 100 may have a multilayered structure that includes a base layer including polymer resin and an inorganic layer. For example, the substrate 100 may include the base layer including polymer resin and a barrier layer of an inorganic insulating layer. For example, the substrate 100 may include a first base layer 101, a first barrier layer 102, a second base layer 103, and a second barrier layer 104 which are sequentially stacked. The first base layer 101 and the second base layer 103 may each include polyimide (PI), polyethersulfone (PES), polyarylate, polyetherimide (PEI), polyethylene napthalate (PEN), polyethylene terephthalate (PET), polyphenylene sulfide (PPS), polycarbonate (PC), cellulose triacetate (TAC), and/or cellulose acetate propionate (CAP). The first barrier layer 102 and the second barrier layer 104 may include an inorganic insulating material, such as silicon oxide (SiO₂), silicon nitride (SiNₓ), and/or silicon oxynitride (SiON). The substrate 100 may be flexible.

The pixel circuit layer PCL may be disposed over the substrate 100. FIG. 2 shows that the pixel circuit layer PCL includes a transistor TFT, and a buffer layer 111, a first gate insulating layer 112, a second gate insulating layer 113, an interlayer insulating layer 114, a first planarization insulating layer 115, and a second planarization insulating layer 116 which are disposed under and/or over components of the transistor TFT.

The buffer layer 111 may decrease or prevent the penetration of foreign materials, moisture, or external air from the bottom of the substrate 100 and provide a flat surface to the substrate 100. The buffer layer 111 may include an inorganic insulating material, such as SiO₂, SiON, or SiNₓ, and may be a layer or layers including the above material.

The transistor TFT on the buffer layer 111 may include a semiconductor layer Act, and the semiconductor layer Act may include polysilicon. Alternatively, the semiconductor layer Act may include amorphous silicon, an oxide semiconductor, an organic semiconductor, or the like. The semiconductor layer Act may include a channel area C and a drain area D and a source area S respectively arranged on both sides of the channel area C. A gate electrode GE may overlap the channel area C.

The gate electrode GE may include a low-resistive metal material. The gate electrode GE may include a conductive material including molybdenum (Mo), aluminum (Al), copper (Cu), or titanium (Ti) and may be a layer or layers including the above material.

The first gate insulating layer 112 between the semiconductor layer Act and the gate electrode GE may include an inorganic insulating material, such as SiO₂, SiNₓ, SiON, aluminum oxide (Al₂O₃), titanium oxide (TiO₂), tantalum oxide (Ta₂O₅), hafnium oxide (HfO₂), or zinc oxide (ZnOₓ). ZnOₓ may be ZnO and/or ZnO₂.

The second gate insulating layer 113 may cover the gate electrode GE. Similar to the first gate insulating layer 112, the second gate insulating layer 113 may include an inorganic insulating material, such as SiO₂, SiNₓ, SiON, Al₂O₃, TiO₂, Ta₂O₅, HfO₂, or ZnOₓ. ZnOₓ may be ZnO and/or ZnO₂.

An upper electrode Cst2 of a storage capacitor Cst may be disposed over the second gate insulating layer 113. The upper electrode Cst2 may overlap the gate electrode GE arranged thereunder. In this case, the gate electrode GE and the upper electrode Cst2, which overlap each other with the second gate insulating layer 113 therebetween, may form the storage capacitor Cst. That is, the gate electrode GE may function as a lower electrode Cst1 of the storage capacitor Cst.

As described, the storage capacitor Cst may overlap the transistor TFT. In some embodiments, the storage capacitor Cst may not overlap the transistor TFT.

The upper electrode Cst2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu and may be a layer or layers including the above material.

The interlayer insulating layer 114 may cover the upper electrode Cst2. The interlayer insulating layer 114 may include SiOₓ, SiNₓ, SiON, Al₂O₃, TiO₂, Ta₂O₅, HfO₂, ZnOₓ, or the like. ZnOₓ may be ZnO and/or ZnO₂. The interlayer insulating layer 114 may be a layer or layers including the above inorganic insulating material.

A drain electrode DE and a source electrode SE may each be disposed over the interlayer insulating layer 114. The drain electrode DE and the source electrode SE may be respectively connected to the drain area D and the source area S through contact holes formed in insulating layers under the drain electrode DE and the source electrode SE. The drain electrode DE and the source electrode SE may each include a material with good conductivity. The source electrode SE and the drain electrode DE may each include a conductive material including Mo, Al, Cu, or Ti and may be a layer or layers including the above material. In an embodiment, the drain electrode DE and the source electrode SE may have a multilayered structure of Ti/Al/Ti.

The first planarization insulating layer 115 may cover the drain electrode DE and the source electrode SE. The first planarization insulating layer 115 may include organic insulating materials, such as a general-purpose polymer such as polymethylmethacrylate (PMMA) or polystyrene (PS), a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, and any blend thereof.

The second planarization insulating layer 116 may be disposed over the first planarization insulating layer 115. The second planarization insulating layer 116 may include the same material as the first planarization insulating layer 115 and may include organic insulating materials, such as a general-purpose polymer such as PMMA or PS, a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, and any blend thereof.

The display element layer DEL may be disposed over the pixel circuit layer PCL having the above-described structure. The display element layer DEL may include an organic light-emitting diode OLED as a display element (that is, the light-emitting element), and the organic light-emitting diode OLED may have a stack structure including a pixel electrode 210, an intermediate layer 220, and a common electrode 230. The organic light-emitting diode OLED may emit, for example, red light, green light, or blue light or emit red light, green light, blue light, or white light. The organic light-emitting diode OLED may emit light through an emission area, and the emission area may be defined as a pixel PX.

The pixel electrode 210 of the organic light-emitting diode OLED may be electrically connected to the transistor TFT through contact holes, which are formed in the second planarization insulating layer 116 and the first planarization insulating layer 115, and a contact metal CM disposed over the first planarization insulating layer 115.

The pixel electrode 210 may include conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 210 may include a reflection film including Ag, Mg, Al, Pt, Pd, Au, Ni, Nd, Ir, Cr, or a compound thereof. In another embodiment, the pixel electrode 210 may further include a film including ITO, IZO, ZnO, or In₂O₃ over/under the above reflection film.

A pixel-defining layer 117 including an opening 117OP is disposed over the pixel electrode 210, the opening 117OP exposing a central portion of the pixel electrode 210. The pixel-defining layer 117 may include an organic insulating material and/or an inorganic insulating material. The opening 117OP may define an emission area of light emitted from the organic light-emitting diode OLED. For example, the size/width of the opening 117OP may correspond to the size/width of the emission area. Therefore, the size and/or the width of the pixel PX may depend on the size and/or the width of the opening 117OP of the pixel-defining layer 117.

The intermediate layer 220 may include an emission layer 222 formed to correspond to the pixel electrode 210. The emission layer 222 may include a high-molecular-weight or low-molecular-weight organic material emitting a certain color of light. Alternatively, the emission layer 222 may include an inorganic emission material or quantum dots.

In an embodiment, the intermediate layer 220 may include a first functional layer 221 and a second functional layer 223 disposed over and under the emission layer 222, respectively. The first functional layer 221 may include, for example, a Hole Transport Layer (HTL) or both an HTL and a Hole Injection Layer (HIL). The second functional layer 223 may be a component disposed over the emission layer 222 and include an Electron Transport Layer (ETL) and/or an Electron Injection Layer (EIL). The first functional layer 221 and/or the second functional layer 223 may each be a common layer formed to entirely cover the substrate 100 like the common electrode 230 described below.

The common electrode 230 may be disposed on the pixel electrode 210. The common electrode 230 may include a conductive material having a low work function. For example, the common electrode 230 may include a transparent (or translucent) layer including Ag, Mg, Al, Pt, Pd, Au, Ni, Nd, Ir, Cr, lithium (Li), Ca, or an alloy thereof. Alternatively, the common electrode 230 may further include a layer including ITO, IZO, ZnO, or In₂O₃ on the transparent (or translucent) layer including the above material. The common electrode 230 may be integrally formed to cover the entire substrate 100.

The encapsulation layer 300 may be disposed over the display element layer DEL and cover the same. The encapsulation layer 300 may include at least one inorganic encapsulation layer and at least one organic encapsulation layer, and in an embodiment, FIG. 2 shows that the encapsulation layer 300 includes a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may each include one or more inorganic materials selected from among Al₂O₃, TiO₂, Ta₂O₅, HfO₂, ZnOₓ, SiO₂, SiNₓ, and SiON. The organic encapsulation layer 320 may include a polymer-based material. The polymer-based material may include acrylic resin, epoxy-based resin, polyimide, polyethylene, and the like. In an embodiment, the organic encapsulation layer 320 may include acrylate. The organic encapsulation layer 320 may be formed by curing a monomer or applying a polymer. The organic encapsulation layer 320 may be transparent.

Although not shown on the encapsulation layer 300, a touch sensor layer may be disposed on the encapsulation layer 300, and an optical functional layer may be disposed over the touch sensor layer. The touch sensor layer may obtain position information according to an external input, e.g., a touch event. The optical functional layer may reduce the reflectivity of light (external light) that is incident towards the display apparatus from the outside and/or may improve the color purity of light emitted from the display apparatus. In an embodiment, the optical functional layer may include a retarder and/or a polarizer. The retarder may be of a film type or a liquid crystal coating type and may include a λ/2 retarder and/or a λ/4 retarder. The polarizer may also be of a film type or a liquid crystal coating type. The film type may include a stretched synthetic resin film, and the liquid crystal coating type may include liquid crystals arranged in a certain arrangement. The retarder and the polarizer may further include a protective film.

An adhesive member may be arranged between the touch electrode layer and the optical functional layer. General adhesive members well-known to one of ordinary skill in the art may be employed without limitation. The adhesive member may be a pressure-sensitive adhesive (PSA).

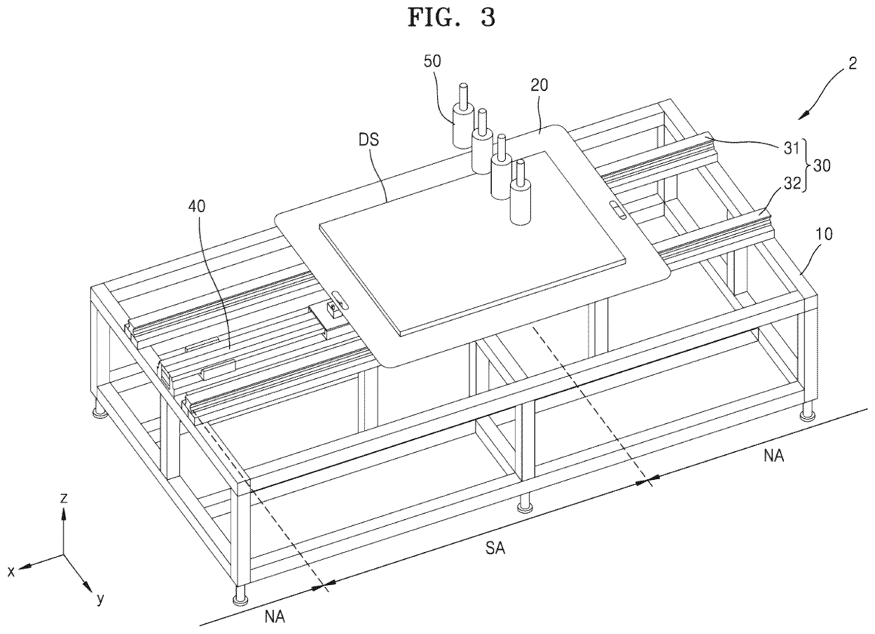

FIG. 3 is a schematic perspective view of a device for inspecting a display apparatus, according to an embodiment.

Referring to FIG. 3, the device 2 for inspecting a display apparatus may be used to inspect the display apparatus 1, for example, a display panel, during the manufacturing process of the display apparatus 1 described above. For example, the device 2 may be used to inspect the curvature of the display panel.

In an embodiment, the device 2 may include a frame 10, a stage 20, an electromagnetic transfer unit 30, and a robotic transfer unit 40.

The frame 10 may function as a framework in which components of the device 2 are mounted and supported. In an embodiment, the frame 10 may have a cuboid shape. That is, the frame 10 may be a beam extending from locations corresponding to the sides of the cuboid.

The stage 20 may be disposed on the frame 10 and transferred to different positions on the frame 10 by transfer units described below. A display substrate DS may be placed on the stage 20 and conveyed according to the transfer of the stage 20. In an embodiment, the stage 20 may have a rectangular cross-section with long sides in a first direction (e.g., an x direction) and short sides in a second direction (e.g., a y direction) crossing the first direction. However, one or more embodiments are not limited thereto, and the stage 20 may have a rectangular cross-section with short sides in the first direction and long sides in the second direction or a square cross-section with four sides of equal length.

In an embodiment, the stage 20 may include an electrostatic chuck using electrostatic force to absorb or desorb the display substrate DS, an adhesive chuck using adhesive force to absorb or desorb the display substrate DS, or a vacuum chuck that absorbs or desorbs the display substrate DS through vacuum absorption.

An electromagnetic transfer unit 30 may be arranged on the frame 10. The electromagnetic transfer unit 30 may be arranged on the frame 10, that is, between the frame 10 and the stage 20. The electromagnetic transfer unit 30 may be arranged on the frame 10 and transfer the stage 20. In an embodiment, two electromagnetic transfer units 30 may be provided in fixed positions and respectively defined as a first electromagnetic transfer unit 31 and a second electromagnetic transfer unit 32. The first electromagnetic transfer unit 31 and the second electromagnetic transfer unit 32 may each extend in the first direction and may be arranged apart from each other in the second direction to be parallel to each other. The electromagnetic transfer unit 30 may use electromagnetic force to transfer the stage 20 in a non-contact manner.

A vision unit 50 may be disposed over the stage 20. In detail, the vision unit 50 may be arranged to face the stage 20 and the display substrate DS on the stage 20. At least one vision unit 50 may be provided, and when there is at least one vision unit 50, the at least one vision unit 50 may be arranged in parallel with each other in the second direction crossing the first direction in which the stage 20 moves. The vision unit 50 may capture the display substrate DS transferred under the vision unit 50 to obtain the image thereof and may inspect the display substrate DS by using the obtained image. For example, the vision unit 50 may obtain the image by inspecting the curvature of the display substrate DS.

In this case, an area, where the display substrate DS is transferred under the vision unit 50 for the inspection of the display substrate DS, may be defined as the inspection area SA. In addition, areas besides the inspection area SA may be defined as the non-inspection area NA. The inspection area SA refers to a section from one side in the first direction (e.g., the side in the +x direction) to the other side (e.g., the side in the −x direction) with the vision unit 50 therebetween. The length of the inspection area SA in the first direction may be set by considering conditions such as inspection types, the speed of the stage, and the image acquisition speed during imaging.

In this case, the stage 20 may be transferred in the non-inspection area NA in the first direction (e.g., the +x direction) and then enter the inspection area SA for the inspection of the display substrate DS. In addition, the stage 20 may pass through the inspection area SA and may be transferred in the non-inspection area NA again. In an embodiment, the path from the non-inspection area NA through the inspection area SA to another non-inspection area NA may be straight, but one or more embodiments are not limited thereto. The path may be bent or curved. In an embodiment, the inspection area SA may be between the non-inspection areas NA. Also, a portion of the path of electromagnetic transfer unit 30 may correspond to the inspection area SA, while other portions thereof may correspond to the non-inspection areas NA.

The robotic transfer unit 40 may be in at least a portion of the path of the electromagnetic transfer unit 30. That is, the robotic transfer unit 40 may have a path that overlaps at least a portion of the path of the electromagnetic transfer unit 30 and does not overlap other portions of the path of the electromagnetic transfer unit 30. In an embodiment, the robotic transfer unit 40 may be in the inspection area SA, but not in the non-inspection area NA. In other words, a portion corresponding to the length from a rear end of the robotic transfer unit 40 to the front end thereof may be defined as the inspection area SA. In this case, in the inspection area SA, the path of the robotic transfer unit 40 may overlap the path of the electromagnetic transfer unit 30. Therefore, the robotic transfer unit 40 may transfer the stage 20 and the display substrate DS mounted on the stage 20 in the inspection area SA.

In an embodiment, the robotic transfer unit 40 may be arranged on the frame 10, that is, between the frame 10 and the stage 20. The robotic transfer unit 40 may be arranged on the frame 10 and transfer the stage 20. In an embodiment, the robotic transfer unit 40 may extend in the first direction and may be arranged between the electromagnetic transfer units 30, for example, the first electromagnetic transfer unit 31 and the second electromagnetic transfer unit 32. In this case, the robotic transfer unit 40 may be arranged to be parallel with the first electromagnetic transfer unit 31 and the second electromagnetic transfer unit 32. Also, the length of the robotic transfer unit 40 (the length in the x direction) may be less than that of each electromagnetic transfer unit 30. The robotic transfer unit 40 may transfer the stage 20 in a contact manner by using the driving force of the motor.

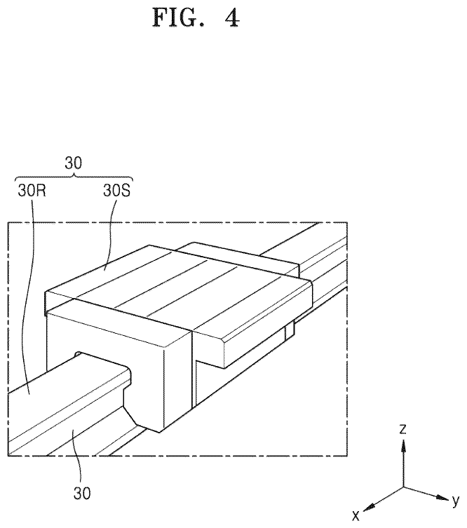

FIG. 4 is a schematic perspective view of an electromagnetic transfer unit according to an embodiment.

Referring to FIGS. 3 and 4, the electromagnetic transfer unit 30 may include a linear magnetic system. That is, each electromagnetic transfer unit 30 may include a rail 30R and a sliding unit 30S. The rail 30R may extend in the first direction and provide a moving path for the sliding unit 30S. The rail 30R may include a plurality of electromagnets, for example, coils. The electromagnets may be arranged along the first direction in which the rail 30R extends, and two adjacent electromagnets among the electromagnets may be controlled to exhibit different polarities. As a result, the polarities of the electromagnets may alternate, resulting in different polarities. The sliding unit 30S may be moved to slide on the rail 30R. In an embodiment, the sliding unit 30S may be arranged to surround at least a portion of the rail 30R, for example, the upper surface and both side surfaces of the rail 30R, and the upper surface of the sliding unit 30S may be coupled to the stage 20. In an embodiment, the sliding unit 30S may include a permanent magnet, and accordingly, the sliding unit 30S may be moved in the first direction by magnetic force with the electromagnets on the rail 30R. As the sliding unit 30S slides on the rail, the stage 20 coupled to the sliding unit 30S may also be moved in the first direction. The stage 20 may be conveyed along the electromagnetic transfer unit 30 by electromagnetic force. In this case, the upper surface of the rail 30R may not be in contact with the sliding unit 30S, achieving a no-contact transfer. In FIG. 3, the sliding unit 30S is not shown because it is covered by the stage 20.

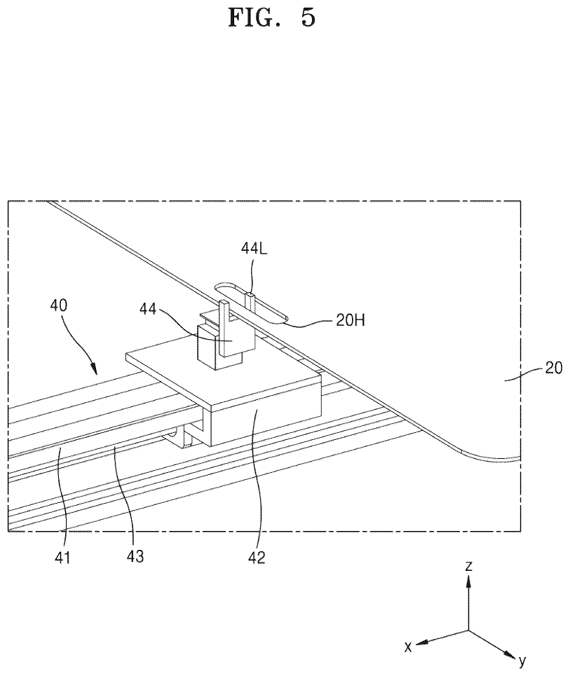

FIG. 5 is an enlarged perspective view schematically showing a robotic transfer unit 40, according to an embodiment.

Referring to FIGS. 3 and 5, the robotic transfer unit 40 may include a guide portion 41 and a moving unit 42. The guide portion 41 may extend in the first direction and provide a movement path for the moving unit 42. The guide portion 41 may extend in the first direction in the inspection area SA. The moving unit 42 may be arranged to surround at least a portion of the guide portion 41. For example, the moving unit 42 may be arranged to surround the entire outer side surface of the guide portion 41. Accordingly, the moving unit 42 may substantially have a U shape and may include a lower member surrounding the lower surface and both side surfaces of the guide portion 41 and an upper member covering the upper surface of the guide portion 41. The moving unit 42 may move along the extension direction of the guide portion 41, that is, along the path of the guide portion 41. The guide portion 41 may stay fixed. A ball screw 43 may be arranged under the guide portion 41. The ball screw 43 may be positioned under the guide portion 41 in the first direction and extend through the lower member of the moving unit 42. The ball screw 43 may include a male screw extending in the first direction, and the lower member of the moving unit 42 may include a through hole with a female thread to allow the male screw to pass through. Accordingly, as the ball screw 43 is rotated by a motor, the moving unit 42 moves in the first direction. The speed at which the moving unit moves in the first direction is controlled by the rotation speed of the ball screw 43. By rotating the ball screw 43 at a constant speed, the moving unit 42 may move at uniform velocity.

Also, in an embodiment, a clamping unit 44 may be arranged on the moving unit 42. The clamping unit 44 may be arranged on the moving unit 42 to clamp the stage 20 such that the stage 20 may be pulled together as the moving unit 42 moves. In an embodiment, the clamping unit 33 may be arranged on the upper surface of the moving unit 42, that is, on the upper member. In this case, the clamping unit 44 may include a protruding rod 44L extending from the upper surface of the moving unit 42. For example, two protruding rods 44L may be provided as a part of a substantially U shape, as in the embodiment of FIG. 5. The stage 20 may include a receiving hole 20H in the front end thereof in the movement direction (e.g., the +x direction) of the stage 20. At least one of the protruding rods 44L protruding in a U shape may extend through the receiving hole 20H, thus engaging with, or clamping, the stage 20. Accordingly, as moving in the first direction (e.g., the +x direction), the moving unit 42 may pull the stage 20. In addition, because the moving unit 42 moves at uniform velocity, the stage 20 pulled by the moving unit 42 may be transferred at uniform velocity on the robotic transfer unit 40.

In addition, FIGS. 3 and 5 show one robotic transfer unit 40, but one or more embodiments are not limited thereto. In an embodiment, there may be a plurality of robotic transfer units 40. In this case, the robotic transfer units 40 may respectively extend in the first direction and may be arranged apart from each other in the second direction to be parallel to each other. In addition, multiple robotic transfer units 40 may be arranged between the first electromagnetic transfer unit 31 and the second electromagnetic transfer unit 32. Alternatively, some of the robotic transfer units 40 may be arranged between the first electromagnetic transfer unit 31 and the second electromagnetic transfer unit 32, while others thereof may be arranged outside the first electromagnetic transfer unit 31 and the second electromagnetic transfer unit 32.

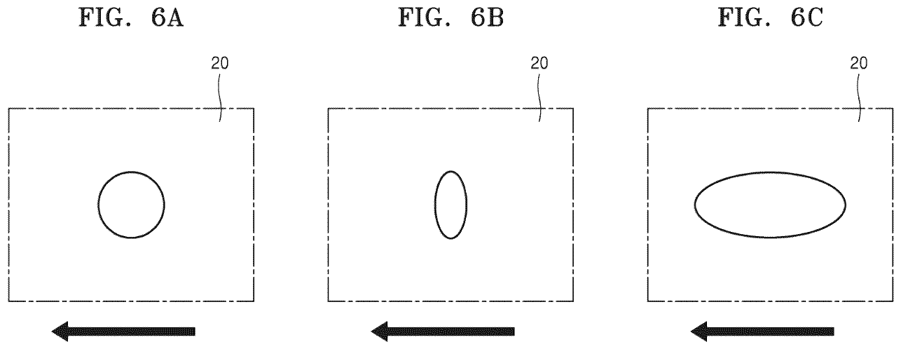

FIG. 6A, FIG. 6B, and FIG. 6C schematically show images captured using a device for inspecting a display apparatus and images according to Comparative Examples and according to an embodiment. FIG. 6B and FIG. 6C depict images captured using comparative examples.

Referring to FIGS. 6A, 6B, and 6C, the device 2 (refer to FIG. 3) for inspecting a display apparatus according to an embodiment may obtain images of improved quality. As in the example of FIG. 6A, a circular object is placed on the stage 20. In this case, when the stage 20 is transferred in the first direction (the x direction) to pass under the vision unit 50, the vision unit 50 may capture images of the object. In this case, according to the speed and acceleration of the stage 20 when the stage 20 passes under the vision unit 50, specifically, through the inspection area SA, image defects may occur as illustrated in the examples of FIG. 6B and FIG. 6C.When the stage 20 is transferred by the electromagnetic transfer unit 30 in the inspection area SA, such image defects may occur. Because the electromagnetic transfer unit 30 adjusts electromagnetic force to transfer the stage 20, the stage 20 may undergo acceleration instead of moving at uniform velocity. That is, during the transfer of the stage 20 in the inspection area SA, a ripple phenomenon may occur where speed variations cause the stage 20 to repeatedly accelerate and decelerate. If the vision unit 50 captures an image of an object while the stage 20 is accelerating, the size of the captured object in the image may appear compressed compared to the actual size of the captured object, as illustrated in FIG. 6B. In addition, when the vision unit 50 captures an image of the object while the stage 20 is decelerating, the size of the captured object in the image may appear stretched compared to the actual size of the captured image, as illustrated in FIG. 6C. Such a difference between the imaged size and the actual size of the object may lead to a decrease in the inspection accuracy of the display apparatus.

According to an embodiment, the stage 20 may be transferred at uniform velocity in the inspection area SA. For example, the robotic transfer unit 40 may transfer the stage 20 at uniform velocity in the inspection area SA. As described above, the moving unit 42 of the robotic transfer unit 40 may move at uniform velocity according to the rotation of the ball screw 43 through a hole in the moving unit 42, and the stage 20 may be pulled at uniform velocity by clamping the stage 20 with the clamping unit 44. Accordingly, the size of the captured object in the image may be the same as the size of the actual object, and the inspection accuracy may be improved.

Referring back to FIG. 3, a method of inspecting a display apparatus according to an embodiment is described. The device 2 for inspecting a display apparatus may be used for the method of inspecting a display apparatus according to an embodiment, but one or more embodiments are not limited thereto.

Referring to FIG. 3, the display substrate DS may be mounted on the stage 20. The display substrate DS is a display apparatus being manufactured and may be placed on the stage 20 of the device 2 for inspection. Alternatively, the display substrate DS may be transferred for inter-process movements, and in this case, the device 2 may be integrated with a transfer device to enable the inspection of the display substrate DS during the transfer of the display substrate DS. In this case, the display substrate DS may be mounted on the stage 20 in the non-inspection area NA.

After the display substrate DS is mounted on the stage 20, the stage 20 may move in the first direction (the +x direction). The stage 20 may be transferred in an acceleration motion by the electromagnetic transfer unit 30 and reach the inspection area SA.

After reaching the inspection area SA, the stage 20 may be transferred by the robotic transfer unit 40 in the first direction. In this case, the electromagnetic transfer unit 30 may not operate. In an embodiment, the clamping unit 44 of the robotic transfer unit 40 is coupled to the stage 20, for example, the receiving hole 20H of the stage 20, thereby clamping the stage 20. In this case, the moving unit 42 may be located on the robotic transfer unit 40, for example, the rear end of the guide portion 41, and thus may be coupled to the front end of the stage 20. The moving unit 42 may be moved in the first direction at uniform velocity because of the rotation of the ball screw 43, and thus, the stage 20 may be pulled in the first direction.

When the stage 20 moves at uniform velocity in the first direction in the inspection area SA, the vision unit 50 may capture the image of the display substrate DS mounted on the stage 20. The vision unit 50 may obtain images and perform a quality inspection of the display substrate DS, for example, a curvature test.

After the moving unit 42 is transferred to the robotic transfer unit 40, for example, to the front end of the guide portion 41, the electromagnetic transfer unit 30 may operate again. Accordingly, the stage 20 entering the non-inspection area NA for the second time after passing through the inspection area SA may be transferred in an acceleration motion by the electromagnetic transfer unit 30.

According to the one or more embodiments, a device for inspecting a display apparatus and a method of inspecting a display apparatus may be provided, which enables easier detection of defects in a display substrate.

The effects of the disclosure are not limited to those stated herein, and other effects that are not mentioned may be clearly understood by one of ordinary skill in the art from the description of claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A device for inspecting a display apparatus, the device comprising:
an electromagnetic transfer unit comprising a first electromagnetic transfer unit extending in a first direction and a second electromagnetic transfer unit spaced apart from and extending parallel to the first electromagnetic transfer unit;
a stage that is arranged on the electromagnetic transfer unit to support a display substrate; and
a robotic transfer unit arranged between the first electromagnetic transfer unit and the second electromagnetic transfer unit and extending in the first direction.

2. The device of claim 1, further comprising a vision unit arranged in an inspection area that includes a segment of a path of the electromagnetic transfer unit for inspection of the display substrate.

3. The device of claim 2, wherein the robotic transfer unit is located in the inspection area on an opposite side of the stage from the vision unit.

4. The device of claim 1, wherein the robotic transfer unit is configured to transfer the stage at uniform velocity.

5. The device of claim 1, wherein a length of the robotic transfer unit is less than a length of the electromagnetic transfer unit.

6. The device of claim 1, wherein a path of the robotic transfer unit overlaps a portion of the path of the electromagnetic transfer unit.

7. The device of claim 1, wherein the robotic transfer unit comprises:
a guide portion extending in a first direction;
a moving unit positioned adjacent to the guide portion and moving along the guide portion; and
a clamping unit arranged on the moving unit and shaped to the stage.

8. The device of claim 7, wherein the robotic transfer unit further comprises a ball screw arranged under the guide portion, extending in the first direction, and comprising a male thread.

9. The device of claim 8, wherein the moving unit comprises a through-hole with a female thread, the ball screw extending through the through-hole and moving the moving unit according to a rotation of the ball screw.

10. The device of claim 7, wherein the clamping unit has a U shape.

11. The device of claim 10, wherein the stage comprises a receiving hole through which at least one end of the U-shaped clamping unit extends.

12. The device of claim 1, wherein the electromagnetic transfer unit comprises a rail comprising a plurality of electromagnets arranged apart from each other in the first direction, and a sliding unit comprising a permanent magnet and configured to slidably move on the rail.

13. The device of claim 1, wherein a plurality of robotic transfer units are provided, and the plurality of robotic transfer units are spaced apart to be parallel with each other and extend in the first direction.

14. A method of inspecting a display apparatus, the method comprising:
mounting a display substrate on a stage;
transferring the stage on an electromagnetic transfer unit;
transferring the stage by a robotic transfer unit in an inspection area for inspection of the display substrate; and
inspecting the display substrate by using a vision unit arranged in the inspection area.

15. The method of claim 14, further comprising transferring the stage along the robotic transfer unit at uniform velocity.

16. The method of claim 15, wherein transferring the stage comprises:
rotating a ball screw that is positioned under a guide portion of the robotic transfer unit and extending in a first direction;
inserting the ball screw through a threaded hole in a moving unit; and
engaging a clamping unit arranged on the moving unit to clamp the stage.

17. The method of claim 16, wherein transferring the stage further comprises rotating the ball screw at a constant speed to move the moving unit at uniform velocity in the first direction in the inspection area.

18. The method of claim 14, further comprising transferring the stage in an accelerated motion along the electromagnetic transfer unit in a non-inspection area.

19. The method of claim 14, wherein the electromagnetic transfer unit comprises a first electromagnetic transfer unit extending in the first direction and a second electromagnetic transfer unit spaced apart from and parallel to the first electromagnetic transfer unit, and
the robotic transfer unit is arranged between the first electromagnetic transfer unit and the second electromagnetic transfer unit and extends in the first direction.

20. The method of claim 14, wherein a the robotic transfer unit is shorter than the electromagnetic transfer unit.
